(19) United States
(12) Patent Application Publication
(10) Pub. No.: US 2024/0088109 A1
(43) Pub. Date: Mar. 14, 2024

(54) SEMICONDUCTOR DEVICE

(71) Applicant: KABUSHIKI KAISHA TOSHIBA, Tokyo (JP)

(72) Inventors: Masahiko KURAGUCHI, Yokohama Kanagawa (JP); Masahiro KOYAMA, Shinagawa Tokyo (JP)

(73) Assignee: KABUSHIKI KAISHA TOSHIBA, Tokyo (JP)

(21) Appl. No.: 18/171,988

(22) Filed: Feb. 21, 2023

(30) Foreign Application Priority Data
Sep. 12, 2022 (JP) 2022-144538

(51) Int. Cl. H01L 25/11; H01L 29/20; H01L 29/778; H01L 29/872

(52) U.S. Cl. CPC H01L 25/115; H01L 29/2003; H01L 29/7786; H01L 29/872; H01L 24/48; H01L 2224/48227

(57) ABSTRACT

According to one embodiment, a semiconductor device includes a first terminal, a second terminal, a third terminal, a first transistor of a normally-off type, a second transistor of a normally-on type, and a diode. The first transistor includes a first source, a first drain, and a first gate. The first source is electrically connected to the first terminal. The first drain is electrically connected to the second terminal. The first gate is electrically connected to the third terminal. The second transistor includes a second source, a second drain, and a second gate. The second drain is electrically connected to the second terminal. The second gate is electrically connected to the first terminal. The diode includes an anode and a cathode. The anode is electrically connected to the first terminal. The cathode is electrically connected to the second source.

### CROSS-REFERENCE TO RELATED APPLICATIONS

This application is based upon and claims the benefit of priority from Japanese Patent Application No. 2022-144538, filed on Sep. 12, 2022; the entire contents of which are incorporated herein by reference.

### FIELD

Embodiments described herein generally relate to a semiconductor device.

### BACKGROUND

For example, in a semiconductor device such as a transistor, improvement in characteristics is desired.

### BRIEF DESCRIPTION OF THE DRAWINGS

FIG. 1 is a circuit diagram illustrating a semiconductor device according to a first embodiment;

FIG. 2 is a circuit diagram illustrating the operation of the semiconductor device according to the first embodiment;

FIG. 3 is a circuit diagram illustrating the operation of the semiconductor device according to the first embodiment;

FIGS. 4A and 4B are graphs illustrating characteristics of semiconductor devices;

FIG. 5 is a schematic view illustrating the semiconductor device according to the first embodiment;

FIG. 6 is a schematic view illustrating the semiconductor device according to the first embodiment;

FIG. 7 is a schematic view illustrating the semiconductor device according to the first embodiment;

FIG. 8 is a schematic cross-sectional view illustrating the semiconductor device according to the first embodiment;

FIG. 9 is a schematic cross-sectional view illustrating a semiconductor device according to a second embodiment;

FIG. 10 is a schematic cross-sectional view illustrating a semiconductor device according to a third embodiment;

FIG. 11 is a schematic cross-sectional view illustrating a semiconductor device according to a fourth embodiment; and

FIG. 12 is a schematic plan view illustrating a semiconductor device according to a fifth embodiment.

### DETAILED DESCRIPTION

According to one embodiment, a semiconductor device includes a first terminal, a second terminal, a third terminal, a first transistor of a normally-off type, a second transistor of a normally-on type, and a diode. The first transistor includes a first source, a first drain, and a first gate. The first source is electrically connected to the first terminal. The first drain is electrically connected to the second terminal. The first gate is electrically connected to the third terminal. The second transistor includes a second source, a second drain, and a second gate. The second drain is electrically connected to the second terminal. The second gate is electrically connected to the first terminal. The diode includes an anode and a cathode. The anode is electrically connected to the first terminal. The cathode is electrically connected to the second source.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

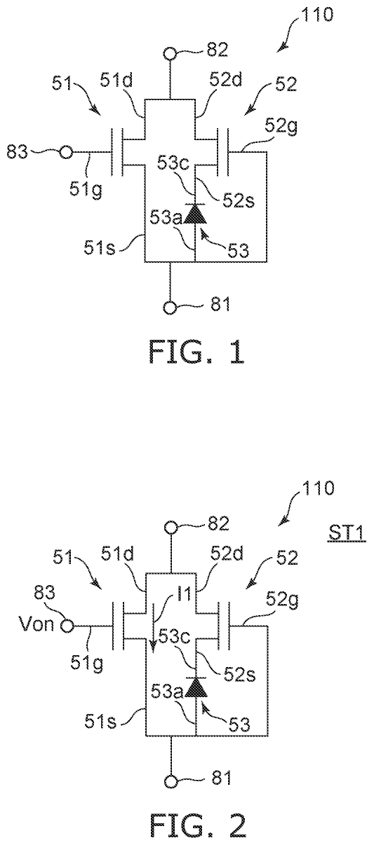

FIG. 1 is a circuit diagram illustrating a semiconductor device according to a first embodiment.

As shown in FIG. 1, a semiconductor device 110 according to the embodiment includes a first terminal 81, a second terminal 82, a third terminal 83, a first transistor 51, a second transistor 52, and a diode 53.

The first transistor 51 is of a normally-off type. The first transistor 51 includes a first source 51s, a first drain 51d and a first gate 51g. The first source 51s is electrically connected to the first terminal 81. The first drain 51d is electrically connected to the second terminal 82. The first gate 51g is electrically connected to the third terminal 83.

The second transistor 52 is of a normally-on type. The second transistor 52 includes a second source 52s, a second drain 52d and a second gate 52g. The second drain 52d is electrically connected to the second terminal 82. The second gate 52g is electrically connected to first terminal 81.

The diode 53 includes an anode 53a and a cathode 53c. The anode 53a is electrically connected to first terminal 81. The cathode 53c is electrically connected to second source 52s.

In the semiconductor device 110, the current flowing between the first terminal 81 and the second terminal 82 can be controlled by a potential of the third terminal 83. The potential of the third terminal 83 may be a potential based on the potential of the first terminal 81, for example. The third terminal 83 functions as a gate terminal of the semiconductor device 110.

In the semiconductor device 110 according to the embodiment, a loss in a circulating can be reduced as described later. A semiconductor device with improved characteristics can be provided.

Examples of characteristics of the semiconductor device 110 will be described below.

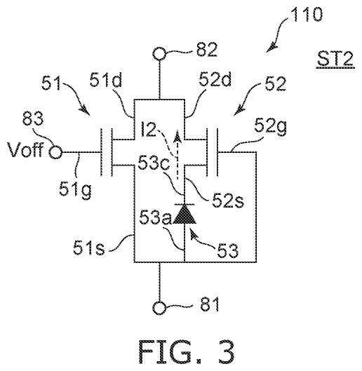

FIGS. 2 and 3 are circuit diagrams illustrating the operation of the semiconductor device according to the first embodiment.

As shown in FIG. 2, in a first state ST1, when the ON voltage Von is applied to the third terminal 83, the first current I1 flows. The first current I1 has a direction from the second terminal 82 to the first terminal 81.

As shown in FIG. 3, a potential of the third terminal 83 becomes an OFF voltage Voff. For example, the OFF voltage Voff is lower than the ON voltage Von. For example, the OFF voltage Voff is the potential of the first terminal 81. Shift from the first state ST1 to the second state ST2 (off state) occurs. In the off state, the potential of the first terminal 81 may be higher than the potential of the second terminal 82 by the configuration of the external circuit. In this case, a second current I2 flows through the second transistor 52. The second current I2 has a direction from the first terminal 81 to the second terminal 82.

For example, switching is repeatedly performed between the first state ST1 and the second state ST2. For example, when the first transistor 51 is in the on-state, the second transistor 52 is in the off-state. For example, when the first transistor 51 is in the off-state, the second transistor 52 is in the on-state. When the potential of the first terminal 81 becomes higher than the potential of the second terminal 82, a current can flow through the first transistor 51 by turning on the first transistor 51. However, a dead time occurs from when the first terminal 81 becomes high potential to when the first transistor 51 becomes the on-state.

The loss occurs in dead time. This corresponds to the loss in the circulation. The loss in the circulation becomes significant, for example, as the switching frequency increases.

In the embodiment, the diode 53 is provided between the second source 52s of the second transistor 52 and the first terminal 81. Thereby, the ON voltage in the dead time can be decreased. As a result, the loss in the circulation can be suppressed.

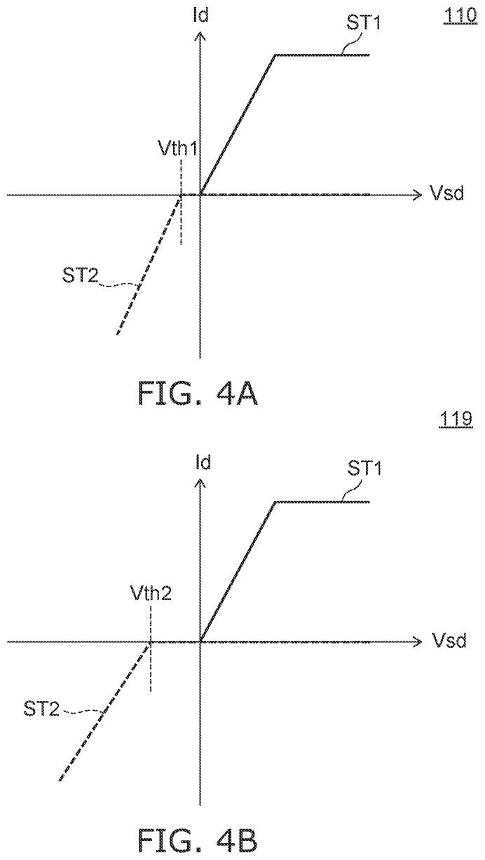

FIGS. 4A and 4B are graphs illustrating characteristics of semiconductor devices.

FIG. 4A corresponds to the semiconductor device 110 according to the embodiment. FIG. 4B corresponds to a semiconductor device 119 of a reference example. In the semiconductor device 119, the first transistor 51 and the second transistor 52 are provided, and the diode 53 is not provided. In the semiconductor device 119, the second source 52s is electrically connected to the first terminal 81. The horizontal axis of these figures is the source-drain voltage Vsd. The source-drain voltage Vsd corresponds to the voltage between the first terminal 81 and the second terminal 82. The vertical axis of these figures is the drain current Id. The drain current Id corresponds to a current flowing between the first terminal 81 and the second terminal 82.

As shown in FIG. 4B, in the semiconductor device 119 of the reference example, the absolute value of the threshold voltage Vth2 is large. As a result, the ON voltage in the dead time is high.

As shown in FIG. 4A, in the semiconductor device 110 according to the embodiment, the absolute value of the threshold voltage Vth1 is smaller than the absolute value of the threshold voltage Vth2. The small threshold voltage Vth1 is due to the diode 53 being provided. In the semiconductor device 110, the ON voltage in the dead time can be decreased. As a result, the loss in the circulation can be reduced. The semiconductor device 110 functions, for example, as an FET (Field effect transistor) having a body diode.

The absolute value of threshold voltage Vth2 is, for example, 3.5V. The absolute value of threshold voltage Vth1 is, for example, 1.2V. For example, in the case of switching at a frequency of 1 MHz at 3 kW, the loss in the circulation is about 0.4 W in the semiconductor device 119. On the other hand, in the semiconductor device 110 under the same conditions, the loss in the circulation is about 0.1 W. According to the embodiment, the loss in the circulation can be suppressed. A semiconductor device with improved characteristics can be provided.

Examples of the configuration of the semiconductor device will be described below.

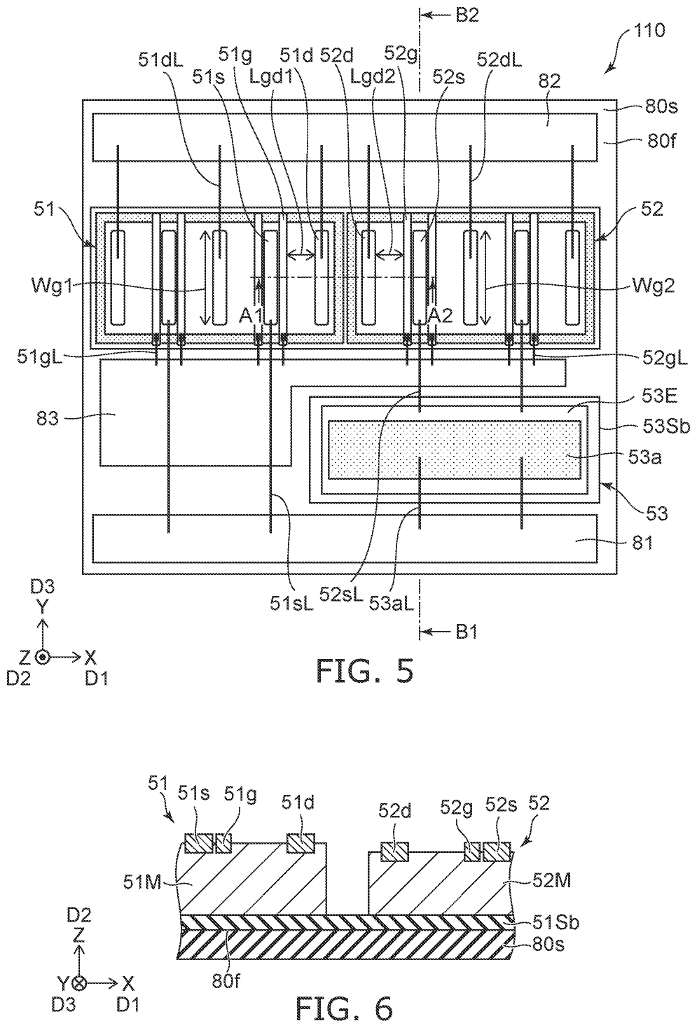

FIGS. 5 to 7 are schematic views illustrating the semiconductor device according to the first embodiment.

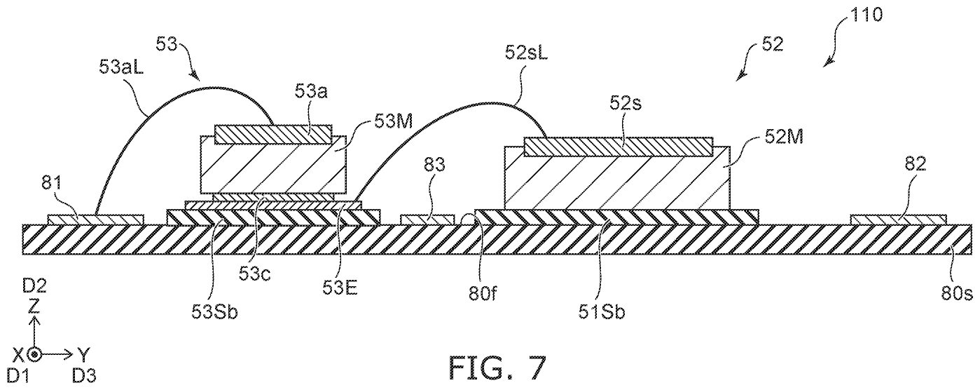

FIG. 5 is a plan view. FIG. 6 is a cross-sectional view taken along the line A1-A2 of FIG. 5. FIG. 7 is a cross-sectional view taken along the line B1-B2 of FIG. 5.

As shown in FIGS. 5 to 7, the semiconductor device 110 further includes a device substrate 80s. The device substrate 80s is, for example, an insulating substrate for mounting components. The device substrate 80s includes a first substrate face 80f. The positions of the first transistor 51, the second transistor 52 and the diode 53 with respect to the first substrate face 80f are fixed.

As shown in FIGS. 5 and 6, a first direction D1 from the first transistor 51 to the second transistor 52 is along a first substrate face 80f. As shown in FIG. 5, the direction from the diode 53 to at least a part of the second transistor 52 is along the first substrate face 80f.

The first direction D1 is defined as an X-axis direction. One direction perpendicular to the X-axis direction is defined as a Z-axis direction. The direction perpendicular to the X-axis direction and the Y-axis direction is defined as a Y-axis direction.

As shown in FIG. 6, a second direction D2 from the first substrate face 80f to the first transistor 51 crosses the first direction D1. The direction from the first substrate face 80f to the second transistor 52 is along the second direction D2. The second direction D2 is, for example, the Z-axis direction.

As shown in FIGS. 5 and 6, a direction from the first source 51s to the first drain 51d is along the first direction D1. A position of the first gate 51g in the first direction D1 is between a position of the first source 51s in the first direction D1 and a position of the first drain 51d in the first direction D1.

As shown in FIGS. 5 and 6, a direction from the second drain 52d to the second source 52s is along the first direction D1. A position of the second gate 52g in the first direction D1 is between a position of the second drain 52d in the first direction D1 and a position of the second source 52s in the first direction D1.

As shown in FIG. 5, the first source 51s, the first drain 51d, the first gate 51g, the second source 52s, the second drain 52d and the second gate 52g extend along a third direction D3. The third direction D3 crosses a plane including the first direction D1 and the second direction D2. The third direction D3 is, for example, the Y-axis direction.

As shown in FIG. 5, in this example, the first terminal 81, the second terminal 82, and the third terminal 83 are fixed to the first substrate face 80f. In this example, a position of the first transistor 51 in the third direction D3 and a position of the second transistor 52 in the third direction D3 are between a position of the first terminal 81 in the third direction D3 and a position of the second terminal 82 in the third direction D3. A position of a part of the third terminal 83 in the third direction D3 is between the position of the first terminal 81 in the third direction D3 and the position of the first transistor 51 in the third direction D3. Another part of the third terminal 83 in the third direction D3 is located between the position of the diode 53 in the third direction D3 and the position of the second transistor 52 in the third direction D3. In embodiments, the positions and plane shapes of the first terminal 81, the second terminal 82, and the third terminal 83 can be varied.

As shown in FIGS. 5 and 6, in this example, the semiconductor device 110 includes a transistor substrate 51Sb. For example, the first transistor 51 and the second transistor 52 are mounted on the transistor substrate 51Sb. The transistor substrate 51Sb is fixed to the device substrate 80s.

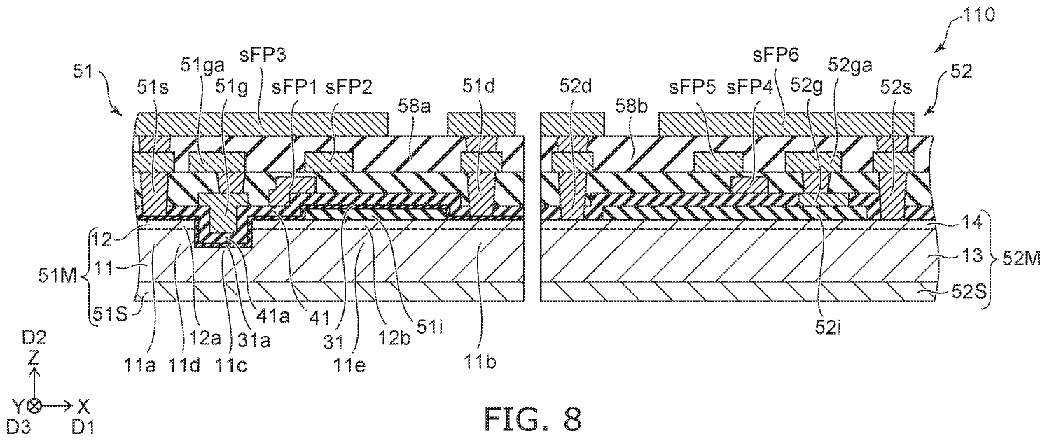

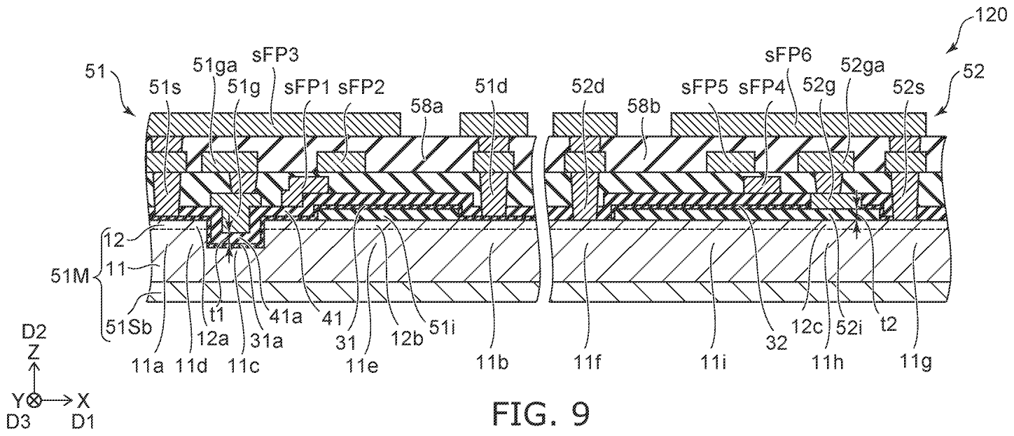

As shown in FIG. 8, the first transistor 51 includes a first transistor semiconductor member 51M. The second transistor 52 includes a second transistor semiconductor member 52M. The second transistor semiconductor member 52M may be separated from the first transistor semiconductor member 51M. The second transistor semiconductor member 52M may be continuous with the first transistor semiconductor member 51M. The first transistor semiconductor member 51M is one semiconductor chip. The second transistor semiconductor member 52M is another semiconductor chip. The first transistor semiconductor member 51M and the second transistor semiconductor member 52M may be different regions of one semiconductor chip.

As will be described later, the first transistor semiconductor member 51M and the second transistor semiconductor member 52M may include GaN. The first transistor 51 and the second transistor 52 include, for example, a nitride semiconductor.

As shown in FIG. 7, in this example, the cathode 53c is located between the first substrate face 80f and the anode 53a. The diode 53 includes a diode semiconductor member 53M. The diode semiconductor member 53M includes silicon. The diode 53 may be a silicon diode.

For example, diode 53 may be a Schottky barrier diode. The breakdown voltage of the diode 53 may be ⅕ or less of the breakdown voltage of the first transistor 51. The breakdown voltage of the diode 53 may be ⅛ or less of the breakdown voltage of the first transistor 51. The breakdown voltage of the diode 53 is equal to or higher than the absolute value of the threshold voltage of the second transistor 52. The intended operation is stably obtained.

As shown in FIG. 7, in this example, the semiconductor device 110 includes a diode substrate 53Sb. The diode 53 is mounted on the diode substrate 53Sb. The diode substrate 53Sb is fixed to the device substrate 80s.

In this example, in the diode substrate 53Sb, a diode conductive layer 53E is provided. The cathode 53c is electrically connected to the diode conductive layer 53E.

As shown in FIGS. 5 and 7, the diode conductive layer 53E and the second source 52s are electrically connected by a second source wiring 52sL. As shown in FIGS. 5 and 7, the anode 53a is electrically connected to the first terminal 81 by an anode wiring 53aL.

As shown in FIG. 5, the first source 51s is electrically connected to the first terminal 81 by a first source wiring 51sL. As shown in FIG. 5, the first gate 51g is electrically connected to the third terminal 83 by a first gate wiring 51gL. As shown in FIG. 5, the second gate 52g is electrically connected to the third terminal 83 by a second gate wiring 52gL. As shown in FIG. 5, the first drain 51d is electrically connected to the second terminal 82 by a first drain wiring 51dL. As shown in FIG. 5, the second drain 52d is electrically connected to the second terminal 82 by a second drain wiring 52dL.

As shown in FIG. 5, a distance along the first direction D1 between the first gate 51g and the first drain 51d is defined as a first distance Lgd1. A distance along the first direction D1 between the second gate 52g and the second drain 52d is defined as a second distance Lgd2. The first distance Lgd1 is preferably substantially the same as the second distance Lgd2. For example, the first distance Lgd1 is preferably not less than 0.8 times and not more than 1.2 times the second distance Lgd2. As a result, for example, two transistors can have substantially the same breakdown voltage.

As shown in FIG. 5, a length along the third direction D3 of a part of the first gate 51g facing the first drain 51d is defined as a first length Wg1. A length along the third direction D3 of a part of the second gate 52g facing the second drain 52d is defined as a second length Wg2. The first length Wg1 is preferably substantially the same as the second length Wg2. For example, the first length Wg1 is preferably not less than 0.8 times and not more than to 1.2 times the second length Wg2. As a result, for example, the two transistors have substantially the same on-resistance.

As shown in FIG. 5, in the first transistor 51, a plurality of first sources 51s, a plurality of first drains 51d, and a plurality of first gates 51g may be provided. A position of one of the plurality of first gates 51g in the first direction D1 is between a position of one of the plurality of first sources 51s in the first direction D1 and a position of one of the plurality of first drains 51d in the first direction D1.

As shown in FIG. 5, in the second transistor 52, a plurality of second sources 52s, a plurality of second drains 52d, and a plurality of second gates 52g may be provided. A position of one the plurality of second gates 52g in the first direction D1 is between a position of one of the plurality of second sources 52s in the first direction D1 and a position of one of the plurality of second drains 52d in the first direction D1.

Examples of the first transistor 51 and the second transistor 52 will be described below.

FIG. 8 is a schematic cross-sectional view illustrating the semiconductor device according to the first embodiment.

FIG. 8 corresponds to a part of the cross section taken along the line A1-A2 in FIG. 5. As shown in FIG. 8, the first transistor 51 includes a first semiconductor region 11 and a second semiconductor region 12. The first transistor 51 may include a first transistor substrate 51S. The first transistor substrate 51S may be, for example, a silicon substrate, a GaN substrate, or a SiC substrate. The first semiconductor region 11, the second semiconductor region 12 and the first transistor substrate 51S are included in the first transistor semiconductor member 51M. The first semiconductor region 11 is provided on the first transistor substrate 51S. The second semiconductor region 12 is provided on the first semiconductor region 11. The first transistor substrate 51S may include a buffer layer and the like.

The first semiconductor region 11 includes Alₓ₁Ga₁₋ₓ₁N (0≤x1<1). The first semiconductor region 11 includes, for example, GaN. The composition ratio x1 is, for example, not less than 0 and not more than 0.1.

The second semiconductor region 12 includes Alₓ₂Ga₁₋ₓ₂N (x1<x2≤1). The second semiconductor region 12 includes AlGaN. The composition ratio x2 is, for example, more than 0.1 and not less than 0.35.

The first semiconductor region 11 includes a first partial region 11a, a second partial region 11b, a third partial region 11c, a fourth partial region 11d and a fifth partial region 11e. A direction from the first partial region 11a to the first source 51s is along the second direction D2. A direction from the second partial region 11b to the first drain 51d is along the second direction D2. A direction from the third partial region 11c to the first gate 51g is along the second direction D2.

A position of the fourth partial region 11d along the first direction D1 is between a position of the first partial region 11a along the first direction D1 and a position of the third partial region 11c along the first direction D1. A position of the fifth partial region 11e along the first direction D1 is between the position of the third partial region 11c along the first direction D1 and a position of the second partial region 11b along the first direction D1.

The second semiconductor region 12 includes a first semiconductor portion 12a and a second semiconductor portion 12b. A direction from the fourth partial region 11d to the first semiconductor portion 12a is along the second direction D2. A direction from the fifth partial region 11e to the second semiconductor portion 12b is along the second direction D2.

At least a part of the first gate 51g is located between the first semiconductor portion 12a and the second semiconductor portion 12b in the first direction D1. For example, a part of the first gate 51g may be between the fourth partial region 11d and the fifth partial region 11e in the first direction D1.

For example, in the fourth partial region 11d and the fifth partial region 11e, a carrier region is formed in a portion facing the second semiconductor region 12. The carrier region is, for example, a two-dimensional electron gas. The first transistor 51 is, for example, a normally-off HEMT.

The first source 51s is electrically connected to the first semiconductor portion 12a. The first drain 51d is electrically connected to the second semiconductor portion 12b.

As shown in FIG. 8, first transistor 51 includes a first insulating layer 41. The first insulating layer 41 includes a first insulating region 41a. The first insulating region 41a is located between the third partial region 11c and the first gate 51g. The first insulating region 41a functions, for example, as a gate insulating film. The first insulating layer 41 includes, for example, silicon and oxygen. The first insulating layer 41 includes, for example, SiO₂.

As shown in FIG. 8, the first transistor 51 may include a first nitride member 31. The first nitride member 31 includes Al_{y1}Ga_{1-y1}N (0<y1≤1). The first nitride member 31 may include AlN, for example. A part of the first nitride member 31 is located between the third partial region 11c and the first insulating region 41a. By providing the part of the first nitride member 31 between the third partial region 11c and the first insulating region 41a, for example, a lower on-resistance can be obtained. The thickness of the first nitride member 31 may be, for example, not less than 0.1 nm and not more than 5 nm.

As shown in FIG. 8, the first transistor 51 may further include a first insulating member 51i. A part of the first insulating member 51i is located between the fifth partial region 11e and another part of the first nitride member 31 in the second direction D2. In one example, the first insulating member 51i includes silicon and nitrogen. The first insulating member 51i includes SiN. By providing the first insulating member 51i, for example, a higher breakdown voltage can be obtained.

As shown in FIG. 8, in the first transistor 51, a first gate wiring layer 51ga may be provided. In the first transistor 51, a first field plate sFP1, a second field plate sFP2 and a third field plate sFP3 may be provided. These conductive members are insulated by an interlayer insulating layer 58a.

As shown in FIG. 8, in this example, the second transistor 52 includes a third semiconductor region 13 and a fourth semiconductor region 14. The second transistor 52 may include a second transistor substrate 52S. The second transistor substrate 52S may be, for example, a silicon substrate, a GaN substrate, or a SiC substrate. The third semiconductor region 13, the fourth semiconductor region 14 and the second transistor substrate 52S are included in the second transistor semiconductor member 52M. The third semiconductor region 13 is provided on the second transistor substrate 52S. The fourth semiconductor region 14 is provided on the third semiconductor region 13. The second transistor substrate 52S may include a buffer layer and the like.

The third semiconductor region 13 includes Alₓ₃Ga₁₋ₓ₃N (0≤x3<1). The third semiconductor region 13 includes GaN, for example. The composition ratio x3 is, for example, not less than 0 and not more than 0.1.

The fourth semiconductor region 14 includes Alₓ₄Ga₁₋ₓ₄N (x3<x4≤1). The fourth semiconductor region 14 includes AlGaN, for example. The composition ratio x4 is, for example, more than 0.1 and not less than 0.35. A part of the fourth semiconductor region 14 is located between the third semiconductor region 13 and the second gate 52g.

The second transistor 52 includes a second insulating member 52i. The second insulating member 52i is located between the part of the fourth semiconductor region 14 and the second gate 52g.

For example, a carrier region is formed in a part of the third semiconductor region 13 facing the fourth semiconductor region 14. The carrier region is, for example, a two-dimensional electron gas. The second transistor 52 is, for example, a normally-on HEMT.

As shown in FIG. 8, in the second transistor 52, a second gate wiring layer 52ga may be provided. In the second transistor 52, a fourth field plate sFP4, a fifth field plate sFP5 and a sixth field plate sFP6 may be provided. These conductive members are insulated by an interlayer insulating layer 58b.

In the example of the semiconductor device 110 illustrated in FIG. 8, the first transistor 51 is one semiconductor chip. The second transistor 52 is another semiconductor chip.

As described below, the first transistor 51 and the second transistor 52 may be provided on one semiconductor chip.

### Second Embodiment

FIG. 9 is a schematic cross-sectional view illustrating a semiconductor device according to a second embodiment.

FIG. 9 is a cross-sectional view corresponding to a part of the cross section taken along line the A1-A2 in FIG. 1. As shown in FIG. 9, the first transistor 51 and the second transistor 52 are provided in a semiconductor device 120 according to the second embodiment. In the semiconductor device 120, the configurations of the first transistor 51 and the second transistor 52 are different from the configurations of the first transistor 51 and the second transistor 52 in the semiconductor device 110. Except for this, the configuration of the semiconductor device 120 may be the same as the configuration of the semiconductor device 110.

In the semiconductor device 120, the semiconductor member included in the second transistor 52 is continuous with the semiconductor member included in the first transistor 51. The configuration of the first transistor 51 in the semiconductor device 120 is the same as the configuration of the first transistor 51 in the semiconductor device 110. An example of the configuration of the second transistor 52 in the semiconductor device 120 will be described below.

As shown in FIG. 9, the first semiconductor region 11 includes a sixth partial region 11f, a seventh partial region 11g and an eighth partial region 11h. The second partial region 11b is located between the fifth partial region 11e and the seventh partial region 11g in the first direction D1. The sixth partial region 11f is located between the second partial region 11b and the seventh partial region 11g. The eighth partial region 11h is between the sixth partial region 11f and the seventh partial region 11g.

A direction from the sixth partial region 11f to the second drain 52d is along the second direction D2. A direction from the seventh partial region 11g to the second source 52s is along the second direction D2. A direction from the eighth partial region 11h to the second gate 52g is along the second direction D2.

The second semiconductor region 12 includes a third semiconductor portion 12c. At least part of the third semiconductor portion 12c is located between the eighth partial region 11h and the second gate 52g.

As shown in FIG. 9, the second transistor 52 includes a second insulating member 52i. A part of the second insulating member 52i is located between the third semiconductor portion 12c and the second gate 52g. The second insulating member 52i functions, for example, as a gate insulating film.

In one example, the second insulating member 52i may include the material included in the first insulating member 51i. The second insulating member 52i, for example, a film serving as the first insulating member 51i is used. Efficient manufacturing is possible. The first insulating member 51i and the second insulating member 52i includes SiN, for example.

As shown in FIG. 9, a thickness along the second direction D2 of the first insulating region 41a is defined as a first thickness t1. The first thickness t1 corresponds to the substantial thickness of the gate insulating film in the first transistor 51. A thickness along the second direction D2 of the second insulating member 52i is defined as a second thickness t2. The second thickness t2 corresponds to the thickness of the gate insulating film in the second transistor 52.

For example, the second thickness t2 may be thinner than the first thickness t1. For example, when the first insulating region 41a includes SiO₂ and the second insulating member 52i includes SiN, there is a difference in dielectric constant between these materials. By applying different thicknesses, for example, for example, it is possible to suppress the absolute value of threshold voltage of the second transistor 52 from becoming higher than necessary.

As shown in FIG. 9, the first semiconductor region 11 may include a ninth partial region 11i. A position of the ninth partial region 11i in the first direction D1 is between the position of the second drain 52d in the first direction D1 and the position of the second gate 52g in the first direction D1.

The second transistor 52 may include a second nitride member 32. The second nitride member 32 includes Al_{y2}Ga_{1-y2}N (0<y2≤1). The second nitride member 32 includes AlN, for example. Another part of second insulating member 52i is located between a part of third semiconductor portion 12c and second nitride member 32. A part of the third semiconductor portion 12c is located between the ninth partial region 11i and the other part of the second insulating member 52i.

### Third Embodiment

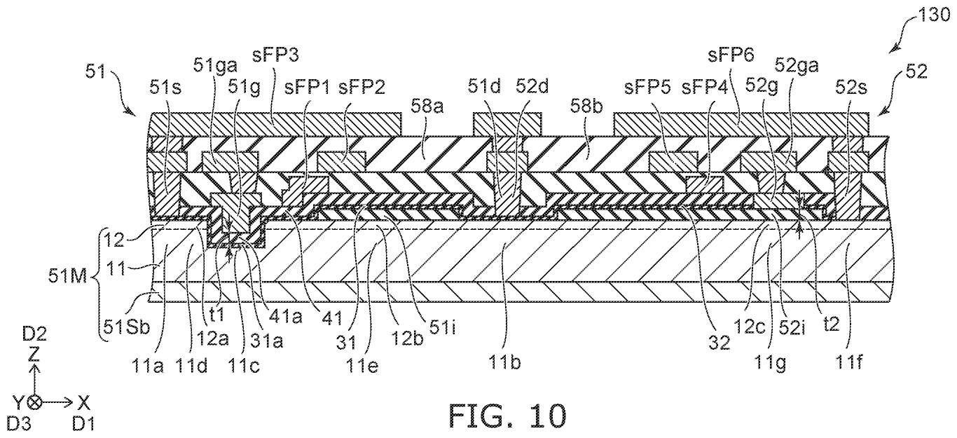

FIG. 10 is a schematic cross-sectional view illustrating a semiconductor device according to a third embodiment.

FIG. 10 is a cross-sectional view corresponding to a part of the cross section taken along the line A1-A2 of FIG. 1. As shown in FIG. 10, the first transistor 51 and the second transistor 52 are provided in a semiconductor device 130 according to the third embodiment. In the semiconductor device 130, the configurations of the first transistor 51 and the second transistor 52 are different from the configurations of the first transistor 51 and the second transistor 52 in the semiconductor device 120. Except for this, the configuration of the semiconductor device 130 may be the same as the configuration of the semiconductor device 120.

In the semiconductor device 130, the drain is shared between the first transistor 51 and the second transistor 52. The configuration of the first transistor 51 in the semiconductor device 130 may be the same as the configuration of the first transistor 51 in the semiconductor device 110.

As shown in FIG. 10, in the semiconductor device 130, the first semiconductor region 11 includes the sixth partial region 11f and the seventh partial region 11g. The second partial region 11b is located between the fifth partial region 11e and the sixth partial region 11f in the first direction D1. The seventh partial region 11g is located between the second partial region 11b and the sixth partial region 11f. A direction from the sixth partial region 11f to the second source 52s is along the second direction D2. A direction from the seventh partial region 11g to the second gate 52g is along the second direction D2.

The second semiconductor region 12 includes the third semiconductor portion 12c. At least a part of the third semiconductor portion 12c is located between the seventh partial region 11g and the second gate 52g.

The second drain 52d is continuous with the first drain 51d. The boundary between the second drain 52d and the first drain 51d may be unclear. The first drain 51d is shared by the first transistor 51 and the second transistor 52.

### Fourth Embodiment

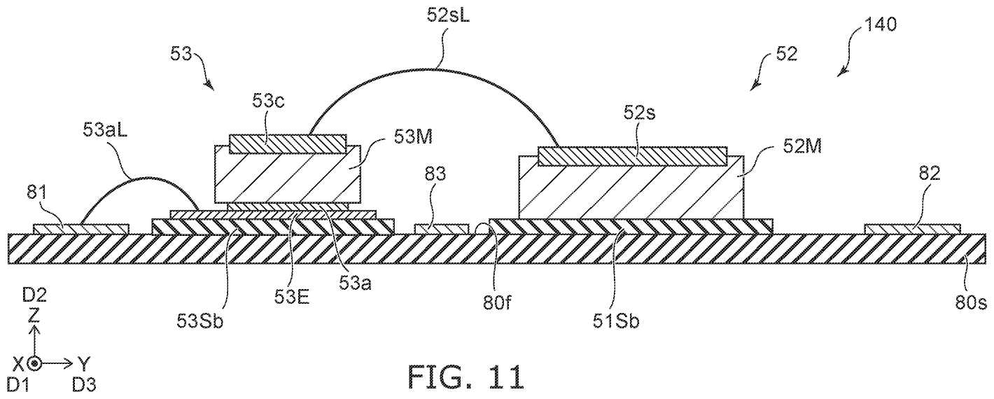

FIG. 11 is a schematic cross-sectional view illustrating a semiconductor device according to a fourth embodiment.

FIG. 11 is a cross-sectional view corresponding to a part of the cross section taken along the line B1-B2 in FIG. 1. As shown in FIG. 11, the diode 53 is provided in a semiconductor device 140 according to the fourth embodiment. The configuration of diode 53 in semiconductor device 140 is different from the configuration of diode 53 in semiconductor device 110. Except for this, the configuration of the semiconductor device 140 may be the same as the configuration of the semiconductor device 110.

As shown in FIG. 11, the semiconductor device 140 includes the device substrate 80s. The device substrate 80s includes the first substrate face 80f. The position of the diode 53 with respect to the first substrate face 80f is fixed. In semiconductor device 140, the anode 53a is located between the first substrate face 80f and the cathode 53c.

The semiconductor device 140 includes the diode substrate 53Sb. The diode 53 is mounted on the diode substrate 53Sb. The diode substrate 53Sb is fixed to the device substrate 80s. The diode conductive layer 53E is provided on the diode substrate 53Sb. The anode 53a is electrically connected to the diode conductive layer 53E. The diode conductive layer 53E is electrically connected to the first terminal 81 by the anode wiring 53aL. The cathode 53c is electrically connected to the second source 52s by the second source wiring 52sL.

The configuration of the diode 53 in the semiconductor device 140 may be applied to the semiconductor device 120 and the semiconductor device 130.

### Fifth Embodiment

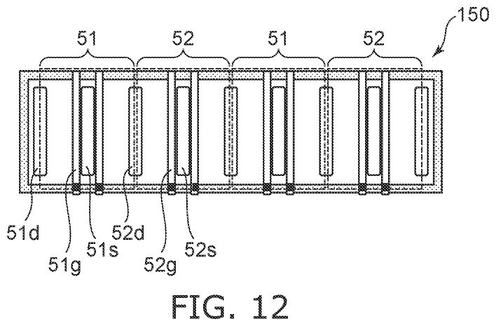

FIG. 12 is a schematic plan view illustrating a semiconductor device according to a fifth embodiment.

As shown in FIG. 12, a semiconductor device 150 according to the fifth embodiment includes a plurality of the first transistors 51 and a plurality of the second transistors 52. One of the plurality of second transistors 52 is provided between one of the plurality of first transistors 51 and another one of the plurality of first transistors 51. One of the plurality of first transistors 51 is provided between one of the plurality of second transistors 52 and another one of the plurality of second transistors 52.

The first source 51s of each of the plurality of first transistors 51 is electrically connected to the first terminal 81 (see FIG. 1). The first gate 51g of each of the plurality of first transistors 51 is electrically connected to the third terminal 83 (see FIG. 1). The first drain 51d of each of the plurality of first transistors 51 is electrically connected to the second terminal 82 (see FIG. 1).

The second source 52s of each of the plurality of second transistors 52 is electrically connected to the cathode 53c (see FIG. 1). The second gate 52g of each of the plurality of second transistors 52 is electrically connected to the first terminal 81 (see FIG. 1). The second drain 52d of each of the plurality of second transistors 52 is electrically connected to the second terminal 82 (see FIG. 1).

In the semiconductor device 150, the first transistor 51 of a normally-off type and the second transistor 52 of a normally-on type are alternately arranged. In the switching, an on-current and a recirculating current efficiently flow through these transistors. For example, the first transistor 51 and the second transistor 52 share the drain electrode. Thereby, effective wiring resistance becomes low. The loss can be more reduced.

Information on length and thickness can be obtained by observing with an electron microscope. Information on the composition can be obtained by SIMS (Secondary Ion Mass Spectrometry) or EDX (Energy dispersive X-ray spectroscopy).

Embodiments may include the following configurations (e.g., technical proposals).

### Configuration 1

A semiconductor device, comprising:
a first terminal;
a second terminal;
a third terminal;
a first transistor of a normally-off type, the first transistor including a first source, a first drain, and a first gate, the first source being electrically connected to the first terminal, the first drain being electrically connected to the second terminal, and the first gate being electrically connected to the third terminal;
a second transistor of a normally-on type, the second transistor including a second source, a second drain, and a second gate, the second drain being electrically connected to the second terminal, and the second gate being electrically connected to the first terminal; and
a diode, the diode including an anode and a cathode, the anode being electrically connected to the first terminal, and the cathode being electrically connected to the second source.

### Configuration 2

The semiconductor device according to Configuration 1, further comprising a device substrate including a first substrate face,
positions of the first transistor, the second transistor, and the diode with respect to the first substrate face being fixed,
a first direction from the first transistor to the second transistor being along the first substrate face, and
a direction from the diode to at least a part of the second transistor being along the first substrate face and crossing the first direction.

### Configuration 3

The semiconductor device according to Configuration 1, further comprising a device substrate including a first substrate face,
a position of the diode with respect to the first substrate face being fixed, and
the cathode being located between the first substrate face and the anode.

### Configuration 4

The semiconductor device according to Configuration 1, further comprising a device substrate including a first substrate face,
a position of the diode with respect to the first substrate face being fixed, and
the anode being located between the first substrate face and the cathode.

### Configuration 5

The semiconductor device according to Configuration 2, wherein
a second direction from the first substrate face to the first transistor crosses the first direction,
a direction from the first substrate face to the second transistor is along the second direction,
a direction from the first source to the first drain is along the first direction,
a position of the first gate in the first direction is between a position of the first source in the first direction and a position of the first drain in the first direction,
a direction from the second drain to the second source is along the first direction,
a position of the second gate in the first direction is between a position of the second drain in the first direction and a position of the second source in the first direction,
the first source, the first drain, the first gate, the second source, the second drain and the second gate are arranged in a third direction, and
the third direction crosses a plane including the first direction and the second direction.

### Configuration 6

The semiconductor device according to Configuration 5, wherein a first distance between the first gate and the first drain along the first direction is not less than 0.8 times and not more than 1.2 times a second distance between the second gate and the second drain along the first direction.

### Configuration 7

The semiconductor device according to Configuration 5 or 6, wherein a first length along the third direction of a part of the first gate facing the first drain is not less than 0.8 times and not more than to 1.2 times a second length along the third direction of a part of the second gate facing the second drain.

### Configuration 8

The semiconductor device according to any one of Configurations 5 to 7, wherein
the first transistor includes:
   a first semiconductor region including Alₓ₁Ga₁₋ₓ₁N (0≤x1<1), and
   a second semiconductor region including Alₓ₂Ga₁₋ₓ₂N (x1<x2≤1),
the first semiconductor region includes a first partial region, a second partial region, a third partial region, a fourth partial region, and a fifth partial region,
a direction from the first partial region to the first source is along the second direction,
a direction from the second partial region to the first drain is along the second direction,
a direction from the third partial region to the first gate is along the second direction,
a position of the fourth partial region along the first direction is between a position of the first partial region along the first direction and a position of the third partial region along the first direction,
a position of the fifth partial region along the first direction is between the position of the third partial region along the first direction and a position of the second partial region along the first direction,
the second semiconductor region includes a first semiconductor portion and a second semiconductor portion,
a direction from the fourth partial region to the first semiconductor portion is along the second direction,
a direction from the fifth partial region to the second semiconductor portion is along the second direction, and
at least a part of the first gate is located between the first semiconductor portion and the second semiconductor portion in the first direction.

### Configuration 9

The semiconductor device according to Configuration 8, wherein
the first transistor further includes a first insulating layer including a first insulating region, and
the first insulating region is located between the third partial region and the first gate.

### Configuration 10

The semiconductor device according to Configuration 9, wherein
the first transistor further includes a first nitride member including Al_{y1}Ga_{1-y1}N (0<y1≤1), and
a part of the first nitride member is located between the third partial region and the first insulating region.

### Configuration 11

The semiconductor device according to Configuration 10, wherein
the first transistor further includes a first insulating member, and
a part of the first insulating member is located between the fifth partial region and another part of the first nitride member.

### Configuration 12

The semiconductor device according to Configuration 11, wherein
the first semiconductor region includes a sixth partial region, a seventh partial region, and an eighth partial region,
the second partial region is located between the fifth partial region and the seventh partial region in the first direction,
the sixth partial region is located between the second partial region and the seventh partial region,
the eighth partial region is located between the sixth partial region and the seventh partial region,
a direction from the sixth partial region to the second drain is along the second direction,
a direction from the seventh partial region to the second source is along the second direction,
a direction from the eighth partial region to the second gate is along the second direction,
the second semiconductor region includes a third semiconductor portion, and
the third semiconductor portion is located between the eighth partial region and the second gate.

### Configuration 13

The semiconductor device according to Configuration 12, wherein
the second transistor further includes a second insulating member,
a part of the second insulating member is located between at least a part of the third semiconductor portion and the second gate, and
the second insulating member includes a material included in the first insulating member.

### Configuration 14

The semiconductor device according to Configuration 13, wherein a second thickness of the second insulating member along the second direction is thinner than a first thickness of the first insulating region along the second direction.

### Configuration 15

The semiconductor device according to Configuration 14, wherein
the second transistor further includes a second nitride member including Al_{y2}Ga_{1-y2}N (0<y2≤1), and
another part of the second insulating member is located between another part of the third semiconductor portion and the second nitride member.

### Configuration 16

The semiconductor device according to Configuration 11, wherein
the first semiconductor region includes a sixth partial region and a seventh partial region,
the second partial region is located between the fifth partial region and the sixth partial region in the first direction,
the seventh partial region is located between the second partial region and the sixth partial region,
a direction from the sixth partial region to the second source is along the second direction,
a direction from the seventh partial region to the second gate is along the second direction,
the second semiconductor region includes a third semiconductor portion,
at least a part of the third semiconductor portion is located between the seventh partial region and the second gate,
the second drain is continuous with the first drain, and
the first drain is shared by the first transistor and the second transistor.

### Configuration 17

The semiconductor device according to any one of Configurations 5 to 7, wherein
the second transistor includes:
   a third semiconductor region including Alₓ₃Ga₁₋ₓ₃N (0≤x3<1),
   a fourth semiconductor region comprising Alₓ₄Ga₁₋ₓ₄N (x3<x4≤1), and
a second insulating member,
a part of the fourth semiconductor region is located between the third semiconductor region and the second gate, and
the second insulating member is located between the part of the fourth semiconductor region and the second gate.

### Configuration 18

The semiconductor device according to Configuration 1, wherein
the diode includes a diode semiconductor member, and
the diode semiconductor member includes silicon.

### Configuration 19

The semiconductor device according to Configuration 1, wherein
the diode is a Schottky barrier diode, and
a breakdown voltage of the diode is not more than ⅕ a breakdown voltage of the first transistor and is not less than an absolute value of a threshold voltage of the second transistor.

### Configuration 20

The semiconductor device according to Configuration 1, wherein
a plurality of the first transistors and a plurality of the second transistors are provided,
one of the plurality of second transistors is located between one of the plurality of first transistors and another one of the plurality of first transistors, and
the one of the plurality of first transistors is located between the one of the plurality of second transistors and another one of the plurality of second transistors.

According to the embodiment, a semiconductor device capable of improving characteristics can be provided.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in semiconductor devices such as terminals, semiconductor members, transistors, diodes, semiconductor regions, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first terminal;
a second terminal;
a third terminal;
a first transistor of a normally-off type, the first transistor including a first source, a first drain, and a first gate, the first source being electrically connected to the first terminal, the first drain being electrically connected to the second terminal, and the first gate being electrically connected to the third terminal;
a second transistor of a normally-on type, the second transistor including a second source, a second drain, and a second gate, the second drain being electrically connected to the second terminal, and the second gate being electrically connected to the first terminal; and
a diode, the diode including an anode and a cathode, the anode being electrically connected to the first terminal, and the cathode being electrically connected to the second source.

2. The device according to claim 1, further comprising a device substrate including a first substrate face,
positions of the first transistor, the second transistor, and the diode with respect to the first substrate face being fixed,
a first direction from the first transistor to the second transistor being along the first substrate face, and
a direction from the diode to at least a part of the second transistor being along the first substrate face and crossing the first direction.

3. The device according to claim 1, further comprising a device substrate including a first substrate face,
a position of the diode with respect to the first substrate face being fixed, and
the cathode being located between the first substrate face and the anode.

4. The device according to claim 1, further comprising a device substrate including a first substrate face,
a position of the diode with respect to the first substrate face being fixed, and
the anode being located between the first substrate face and the cathode.

5. The device according to claim 2, wherein
a second direction from the first substrate face to the first transistor crosses the first direction,
a direction from the first substrate face to the second transistor is along the second direction,
a direction from the first source to the first drain is along the first direction,
a position of the first gate in the first direction is between a position of the first source in the first direction and a position of the first drain in the first direction,
a direction from the second drain to the second source is along the first direction,
a position of the second gate in the first direction is between a position of the second drain in the first direction and a position of the second source in the first direction,
the first source, the first drain, the first gate, the second source, the second drain and the second gate are arranged in a third direction, and
the third direction crosses a plane including the first direction and the second direction.

6. The device according to claim 5, wherein a first distance between the first gate and the first drain along the first direction is not less than 0.8 times and not more than 1.2 times a second distance between the second gate and the second drain along the first direction.

7. The device according to claim 5, wherein a first length along the third direction of a part of the first gate facing the first drain is not less than 0.8 times and not more than to 1.2 times a second length along the third direction of a part of the second gate facing the second drain.

8. The device according to claim 5, wherein
the first transistor includes:
a first semiconductor region including Alₓ₁Ga₁₋ₓ₁N (0≤x1<1), and
a second semiconductor region including Alₓ₂Ga₁₋ₓ₂N (x1<x2≤1),
the first semiconductor region includes a first partial region, a second partial region, a third partial region, a fourth partial region, and a fifth partial region,
a direction from the first partial region to the first source is along the second direction,
a direction from the second partial region to the first drain is along the second direction,
a direction from the third partial region to the first gate is along the second direction,
a position of the fourth partial region along the first direction is between a position of the first partial region along the first direction and a position of the third partial region along the first direction,
a position of the fifth partial region along the first direction is between the position of the third partial region along the first direction and a position of the second partial region along the first direction,
the second semiconductor region includes a first semiconductor portion and a second semiconductor portion,
a direction from the fourth partial region to the first semiconductor portion is along the second direction,
a direction from the fifth partial region to the second semiconductor portion is along the second direction, and
at least a part of the first gate is located between the first semiconductor portion and the second semiconductor portion in the first direction.

9. The device according to claim 8, wherein
the first transistor further includes a first insulating layer including a first insulating region, and
the first insulating region is located between the third partial region and the first gate.

10. The device according to claim 9, wherein
the first transistor further includes a first nitride member including Al_{y1}Ga_{1-y1}N (0<y1≤1), and
a part of the first nitride member is located between the third partial region and the first insulating region.

11. The device according to claim 10, wherein
the first transistor further includes a first insulating member, and
a part of the first insulating member is located between the fifth partial region and another part of the first nitride member.

12. The device according to claim 11, wherein
the first semiconductor region includes a sixth partial region, a seventh partial region, and an eighth partial region,
the second partial region is located between the fifth partial region and the seventh partial region in the first direction,
the sixth partial region is located between the second partial region and the seventh partial region,
the eighth partial region is located between the sixth partial region and the seventh partial region,
a direction from the sixth partial region to the second drain is along the second direction,
a direction from the seventh partial region to the second source is along the second direction,
a direction from the eighth partial region to the second gate is along the second direction,
the second semiconductor region includes a third semiconductor portion, and
the third semiconductor portion is located between the eighth partial region and the second gate.

13. The device according to claim 12, wherein
the second transistor further includes a second insulating member,
a part of the second insulating member is located between at least a part of the third semiconductor portion and the second gate, and
the second insulating member includes a material included in the first insulating member.

14. The device according to claim 13, wherein a second thickness of the second insulating member along the second direction is thinner than a first thickness of the first insulating region along the second direction.

15. The device according to claim 14, wherein
the second transistor further includes a second nitride member including Al_{y2}Ga_{1-y2}N (0<y2≤1), and
another part of the second insulating member is located between another part of the third semiconductor portion and the second nitride member.

16. The device according to claim 11, wherein
the first semiconductor region includes a sixth partial region and a seventh partial region,
the second partial region is located between the fifth partial region and the sixth partial region in the first direction,
the seventh partial region is located between the second partial region and the sixth partial region,
a direction from the sixth partial region to the second source is along the second direction,
a direction from the seventh partial region to the second gate is along the second direction,
the second semiconductor region includes a third semiconductor portion,
at least a part of the third semiconductor portion is located between the seventh partial region and the second gate,
the second drain is continuous with the first drain, and
the first drain is shared by the first transistor and the second transistor.

17. The device according to claim 5, wherein
the second transistor includes:
a third semiconductor region including Alₓ₃Ga₁₋ₓ₃N (0≤x3<1),
a fourth semiconductor region comprising Alₓ₄Ga₁₋ₓ₄N (x3<x4≤1), and
a second insulating member,
a part of the fourth semiconductor region is located between the third semiconductor region and the second gate, and
the second insulating member is located between the part of the fourth semiconductor region and the second gate.

18. The device according to claim 1, wherein
the diode includes a diode semiconductor member, and
the diode semiconductor member includes silicon.

19. The device according to claim 1, wherein
the diode is a Schottky barrier diode, and
a breakdown voltage of the diode is not more than ⅕ a breakdown voltage of the first transistor and is not less than an absolute value of a threshold voltage of the second transistor.

20. The device according to claim 1, wherein
a plurality of the first transistors and a plurality of the second transistors are provided,
one of the plurality of second transistors is located between one of the plurality of first transistors and another one of the plurality of first transistors, and
the one of the plurality of first transistors is located between the one of the plurality of second transistors and another one of the plurality of second transistors.
